(19) United States
(12) Patent Application Publication
(10) Pub. No.: US 2023/0057596 A1
(43) Pub. Date: Feb. 23, 2023

(54) TEMPERATURE STIMULUS PRESENTATON DEVICE AND METHOD

(71) Applicant: Nippon Telegraph and Telephone Corporation, Tokyo (JP)

(72) Inventors: Arinobu NIIJIMA, Musashino-shi, Tokyo (JP); Toki TAKEDA, Musashino-shi, Tokyo (JP); Takafumi MUKOUCHI, Musashino-shi, Tokyo (JP); Takashi SATO, Musashino-shi, Tokyo (JP)

(21) Appl. No.: 17/796,960

(22) PCT Filed: Feb. 7, 2020
(86) PCT No.: PCT/JP2020/004746

§ 371 Date: Aug. 2, 2022

(51) Int. Cl. G08B 6/00

(52) U.S. Cl. CPC G08B 6/00; H01L 35/28

(57) ABSTRACT

A device includes: a Peltier element 10 that presents a temperature stimulus; and a temperature stimulus control unit 20 that cause the Peltier element 10 to generate a cold stimulus or a hot stimulus by receiving an input of type information which represents the type of information to be notified of and switching the direction of a current that flows through the Peltier element 10 in correspondence with the type information.

### TECHNICAL FIELD

The present invention relates to a temperature stimulus presentation device and a temperature stimulus presentation method in which a Peltier element is used.

### BACKGROUND ART

There has been an increasing demand for a notification method in which tactile feedback is used along with the spread of smartphones and smartwatches. In one method in which tactile feedback is used, a device body is vibrated using a vibrator to allow a user to perceive a tactile stimulus.

Vibration feedback is commonly used for wearable devices. Vibration feedback is often used for push notifications which are made to present information from the system side. PTL 1 discloses a vibration presentation device that allows a person to perceive a plurality of types of vibration, for example.

### CITATION LIST

### Patent Literature

[PTL 1] Japanese Patent Application Publication No. 2015-60274

### SUMMARY OF THE INVENTION

### Technical Problem

With the method disclosed in PTL 1, however, it is difficult to allow one to distinguishably perceive a plurality of types of vibration in the case where notifications are made from a large number of applications. In addition, one may feel annoyed if the terminal vibrates frequently. In order to implement pull notifications which are made by the terminal taking information from the system with vibration feedback, it is necessary to add a switch for detecting the timing to present a vibration stimulus. In addition, it is difficult to distinguish push notifications and pull notifications with only vibration.

Thus, there is an issue that there are no suitable devices or methods to present a plurality of types of information with a single device (e.g. a vibrator) through the tactile feedback according to the related art.

The present invention has been made in view of such an issue, and has an object to provide a temperature stimulus presentation device and a temperature stimulus presentation method that can indicate a plurality of types of information with a single device.

### Means for Solving the Problem

An aspect of the present invention provides a temperature stimulus presentation device including: a Peltier element that presents a temperature stimulus; and a temperature stimulus control unit that cause the Peltier element to generate a cold stimulus or a hot stimulus by receiving an input of type information which represents a type of information to be notified of and switching a direction of a current that flows through the Peltier element in correspondence with the type information.

Another aspect of the present invention provides a temperature stimulus presentation method employed by the above temperature stimulus presentation device, including: a reception step of receiving type information which represents a type of information to be notified of; and a temperature stimulus control step of causing a Peltier element to generate a cold stimulus or a hot stimulus by switching a direction of a current that flows through the Peltier element in accordance with whether or not the type information represents a notification with high urgency.

### Effects of the Invention

With the present invention, a plurality of types of information can be indicated with a single device (Peltier element).

### BRIEF DESCRIPTION OF DRAWINGS

FIG. 1 is a block diagram illustrating an example of the functional configuration of a temperature stimulus presentation device according to an embodiment of the present invention.

FIG. 2 is a schematic diagram illustrating the principle of a Peltier element and a temperature stimulus control unit illustrated in FIG. 1.

FIG. 3 is a block diagram illustrating an example of a schematic configuration for a case where the temperature stimulus presentation device illustrated in FIG. 1 is implemented in a smartwatch.

FIG. 4 is a flowchart illustrating the process procedures of a temperature stimulus presentation method employed by the temperature stimulus presentation device illustrated in FIG. 1.

### DESCRIPTION OF EMBODIMENTS

An embodiment of the present invention will be described below with reference to the drawings. The same elements in a plurality of drawings are given the same reference numerals in order not to repeat description.

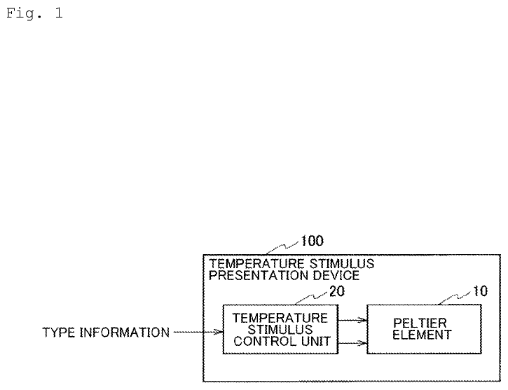

FIG. 1 is a block diagram illustrating an example of the functional configuration of a temperature stimulus presentation device according to an embodiment of the present invention. A temperature stimulus presentation device 100 illustrated in FIG. 1 receives an input of type information which represents the type of information to be indicated, and presents different temperature stimuli in correspondence with the type information. The temperature stimuli to be described in relation to the present embodiment include two types, namely a cold stimulus and a hot stimulus.

The temperature stimulus presentation device 100 includes a Peltier element 10 and a temperature stimulus control unit 20. In the temperature stimulus presentation device 100 illustrated in FIG. 1, only main portions for the present embodiment are indicated, and common functional components such as a power source are omitted.

The Peltier element 10 presents a temperature stimulus. The Peltier element 10 is a type of a plate-shaped semiconductor thermoelectric element that uses the Peltier effect, and is a typical one. The Peltier element 10 will be discussed in detail later.

The temperature stimulus control unit 20 receives an input of type information which represents the type of information to be indicated, and switches the direction of a current that flows through the Peltier element 10 in correspondence with the type information. Examples of the type information include information indicating that there is an incoming call from a known telephone number, and information indicating that there is an incoming call from an unknown telephone number. The former incoming call is assumed to be a call from a family member or a business associate, and should be handled immediately. Meanwhile, the latter incoming call is assumed to be a call from a sales person etc., and may not be handled immediately.

The Peltier element 10 presents two types of temperature stimuli, namely a hot stimulus and a cold stimulus, in accordance with the direction of a current supplied from the temperature stimulus control unit 20. A reference literature (Lynette A. Jones and Hsin-Ni Ho, “Warm or cool, large or small? The challenge of thermal displays” (2008)) indicates that humans perceive hot stimuli and cold stimuli significantly differently.

According to the reference literature, humans perceive cold stimuli better than hot stimuli, and this tendency is more remarkable as the area in which the temperature stimulus is presented is smaller. Hence, it is desirable that push notifications, for example, which should be promptly checked by the user, should be presented through cold stimuli, and that pull notifications, for example, which have been acknowledged by the user, should be presented through hot stimuli. For the pull notifications, the terminal acts to take information from the system, and thus it is only necessary that the user should be notified that the information has been acquired.

As described above, the temperature stimulus presentation device 100 according to the present embodiment includes the Peltier element 10 which presents a temperature stimulus, and the temperature stimulus control unit 20 which receives an input of type information which represents the type of information to be indicated, and which switches the direction of a current that flows through the Peltier element 10 in correspondence with the type information. Consequently, a plurality of types (two types in the above example) of information can be indicated with a single device (Peltier element).

The temperature stimulus control unit 20 preferably switches the direction of a current that flows through the Peltier element 10 to a direction that causes the Peltier element 10 to generate a cold stimulus in the case where the type information indicates a notification with high urgency. Consequently, the user can be informed of the acquisition of an urgent notification immediately and reliably.

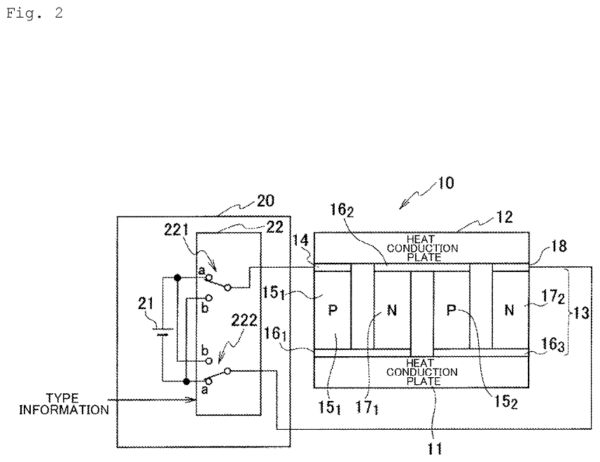

FIG. 2 is a schematic diagram illustrating the principle of the Peltier element 10 and the temperature stimulus control unit 20. Various portions will be described with reference to FIG. 2.

(Peltier Element)

The Peltier element 10 is constituted by sandwiching a thermoelectric module 13 between two heat conduction plates 11 and 12 to allow heat to be transferred from one heat conduction plate 11 to the other heat conduction plate 12. The heat conduction plates 11 and 12 are constituted from a material, e.g. a copper material, that has a relatively high heat conductivity and that is inexpensive.

The thermoelectric module 13 includes a positive electrode 14, p-type thermoelectric materials 15₁, 15₂, common electrodes 16₁, 16₂, 16₃, n-type thermoelectric materials 17₁, 17₂, and a negative electrode 18. Each of the heat conduction plates 11 and 12 is insulated from each of the electrodes (the positive electrode 14, the negative electrode 18, and the common electrodes 16₁, 16₂, 16₃) by an insulating layer (not illustrated).

The plus pole of a power source 21 is connected to the positive electrode 14, and the minus pole of the power source 21 is connected to the negative electrode 18. Then, the positive holes of the p-type thermoelectric materials 17₁ and 17₂ are moved from the heat conduction plate 12 toward the heat conduction plate 11. In addition, the electrons of the n-type thermoelectric materials 15₁ and 15₂ are also moved from the heat conduction plate 12 toward the heat conduction plate 11. Heat around the heat conduction plates 11 and 12 is carried by the positive holes and the electrons serving as carriers. Thus, in this example, the heat conduction plate 12 functions as a heat absorption plate, and the heat conduction plate 11 functions as a heat radiation plate. Hereinafter, the heat conduction plates 12 and 11 will be occasionally referred to as a “heat absorption plate 12” and a “heat radiation plate 11”.

When a current is caused to flow in the opposite direction, meanwhile, the positive holes and the electrons are moved in the opposite direction. Thus, the heat conduction plate 12 functions as a heat radiation plate, and the heat conduction plate 11 functions as a heat absorption plate. In the example illustrated in FIG. 2, the n-type thermoelectric materials 15 and the p-type thermoelectric materials 17 are stacked in only two layers in order to illustrate the principle of the Peltier element 10. In order to obtain practical heat generation and heat absorption functions, the n-type thermoelectric materials 15 and the p-type thermoelectric materials 17 are stacked in a large number of layers.

Two types of temperature stimuli, namely a hot stimulus and a cold stimulus, can be presented by allowing one of the heat conduction plates 11 (12) of the Peltier element 10, which functions to radiate heat and absorb heat by supplying a current in this manner, to contact a human skin.

(Temperature Stimulus Control Unit)

The temperature stimulus control unit 20 includes the power source 21 and a switching unit 22. The power source 21 may be any of a battery, a current source, and a voltage source. The switching unit 22 switches to connect one of the plus pole and the minus pole of the power source 21 to the positive electrode 14 of the thermoelectric module 13 in correspondence with the type information. Similarly, the switching unit 22 switches to connect one of the minus pole and the plus pole to the negative electrode 18 of the thermoelectric module 13.

In principle, the function of the switching unit 22 can be represented by two single-pole double-throw switches (SPDTs) 221 and 222. Hereinafter, the single-pole double-throw switches will be referred to as “switches”.

As illustrated in FIG. 2, the switch 221 switches to connect one of the plus pole and the minus pole of the power source 21 to the positive electrode 14 of the thermoelectric module 13. The switch 222 switches to connect one of the minus pole and the plus pole to the negative electrode 18 of the thermoelectric module 13.

The switches 221 and 222 operate in conjunction with each other so that, when the switch 221 selects a terminal a, the switch 222 also selects a terminal a. The same also applies to a terminal b.

In the case where the type information represents a notification with high urgency, the switches 221 and 222 are each connected to the terminal a, for example. Hence, the heat conduction plate 12 functions as a heat absorption plate, and thus a cold stimulus can be presented by placing the heat conduction plate in contact with a human skin.

In the case where the type information represents a notification with low urgency, meanwhile, the switches 221 and 222 are each connected to the terminal a, for example. In this case, the heat conduction plate 12 functions as a heat radiation plate, and thus a hot stimulus can be presented.

The switches 221 and 222 can each be constituted of two relays. Two types of information (a hot stimulus and a cold stimulus) can be indicated by switching the relays in correspondence with the type information as binary information (1/0), for example.

(Implementation Example)

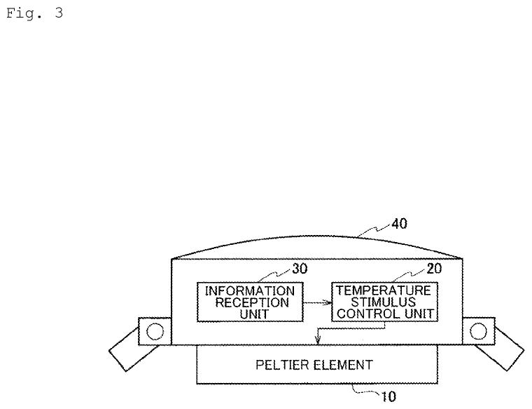

FIG. 3 schematically illustrates an example of a case where the temperature stimulus presentation device 100 according to the present embodiment is implemented in a smartwatch. The temperature stimulus presentation device 100 (the temperature stimulus control unit 20 and the Peltier element 10) is implemented in a smartwatch 40.

An information reception unit 30 illustrated in FIG. 3 receives information to be handled, and outputs the received information to the temperature stimulus control unit 20. The operation of the temperature stimulus control unit 20 and the Peltier element 10 after the information to be handled is input is the same as that described above.

Both ends of the smartwatch 40 are portions to be fitted with a belt to be mounted on a wrist. Reference numerals of the belt and the portions to be fitted are omitted. The Peltier element 10 is disposed on the surface of the case back of the smartwatch 40 in such a direction that the heat conduction plate 12 contacts a skin, for example. In this manner, the Peltier element 10 is disposed so as to contact a human skin.

When the smartwatch 40 is mounted on a wrist, the heat conduction plate 12 of the Peltier element 10 contacts the skin of the wrist. In the case where the type information received by the information reception unit 30 represents a notification with high urgency, the temperature stimulus control unit 20 switches the switching unit 22 such that a current flows from the positive electrode 14 toward the negative electrode 18 of the thermoelectric module 13. In this case, the heat conduction plate 12 functions as a heat absorption plate, and thus the user perceives a cold stimulus on his/her wrist. Since a cold stimulus is perceived with high sensitivity, the user can be informed of the acquisition of a notification with high urgency immediately and reliably.

In the case where the type information received by the information reception unit 30 represents a notification with low urgency, the heat conduction plate 12 functions as a heat radiation plate, and thus the user perceives a hot stimulus on his/her wrist. Although a hot stimulus is not perceived with so high sensitivity as a cold stimulus, the user can still be informed that information has been acquired.

In this case, the heat conduction plate 11 on the opposite side functions as a heat absorption plate. Thus, the heat conduction plate 11 and a side surface of the case of the smartwatch 40 or a part of the case on the side of a display surface may be connected to each other through a material with a high heat conductivity so that a cold stimulus can be felt on the side surface of the case of the smartwatch 40 or the part of the case on the side of the display surface.

In the case where a cold stimulus is presented on the side surface of the case of the smartwatch 40 or the part of the case on the side of the display surface, the user does not perceive the cold stimulus before he/she touches the side surface of the case of the smartwatch 40 or the part of the case on the side of the surface with his/her finger. It may be indicated (specified) that a notification with low urgency has been acquired in the case where a cold stimulus is received on the side surface of the case or the surface in this manner. In this case, a hot stimulus is perceived on the skin of the wrist.

(Temperature Stimulus Presentation Method)

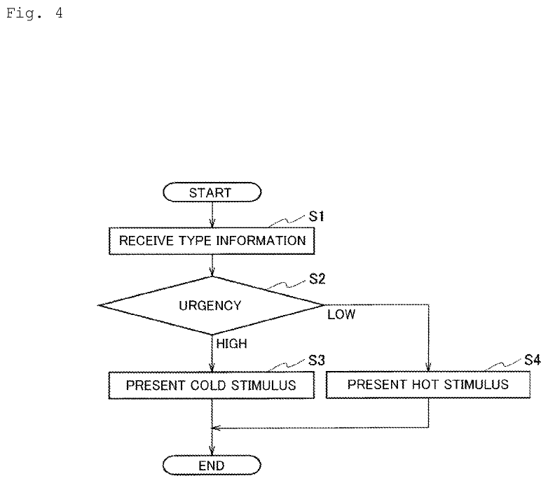

FIG. 4 is a flowchart illustrating the process procedures of a temperature stimulus presentation method employed by the temperature stimulus presentation device 100 according to the present embodiment.

The information reception unit 30 receives type information that represents the type of information to be indicated (step S1). The type information may be contradictory information that indicates high urgency or low urgency, for example.

The temperature stimulus control unit 20 determines whether or not the type information received by the information reception unit 30 represents a notification with high urgency (step S2).

In the case where the type information represents a notification with high urgency, the Peltier element 10 is caused to generate a cold stimulus (step S3). In the case where the heat conduction plate 12 of the Peltier element 10 is in contact with the skin of the user, a current is caused to flow from the positive electrode 14 toward the negative electrode 18 of the thermoelectric module 13.

In the case where the type information represents a notification with low urgency, the Peltier element 10 is caused to generate a hot stimulus (step S4). In the case where the heat conduction plate 12 of the Peltier element 10 is in contact with the skin of the user, a current is caused to flow from the negative electrode 18 toward the positive electrode 14 of the thermoelectric module 13.

In this manner, the temperature stimulus presentation method according to the present embodiment is a temperature stimulus presentation method employed by the temperature stimulus presentation device 100, and includes a reception step S1 of receiving type information which represents the type of information to be indicated, and a temperature stimulus control step S3 and S4 of causing the Peltier element 10 to generate a cold stimulus or a hot stimulus by switching the direction of a current that flows through the Peltier element 10 in accordance with whether the type information represents a notification with high urgency (Yes in step S2) or not (No in step S2). Consequently, two types of information, namely a cold stimulus and a hot stimulus, can be indicated with a single Peltier element 10 in correspondence with the type information.

With the present invention, as has been described above, it is possible to generate a plurality of types of stimuli, namely a cold stimulus and a hot stimulus, with a single Peltier element 10. In addition, the types of notifications can be distinguished easily compared to the vibration feedback according to the related art. For example, it is easy to distinguish push notifications and pull notifications. In addition, one does not feel annoyed with the vibration feedback.

While the type information is contradictory binary information that indicates high urgency or low urgency, for example, in the embodiment described above, the present invention is not limited to such an example. The type information may be multivalued information with two or more values.

For example, in the case where the type information indicates high, medium, or low urgency, for example, a cold stimulus may be presented with different current values, for example, when the type information indicates high or medium urgency, and a hot stimulus may be presented in the case where the type information indicates low urgency. That is, the temperature stimulus control unit 20 may be configured to cause the Peltier element to generate a cold stimulus or a hot stimulus by receiving an input of type information which represents the type of information to be indicated and switching the direction and the magnitude of a current that flows through the Peltier element 10 in correspondence with the type information.

While the temperature stimulus presentation device 100 is implemented in the smartwatch 40 in the described example, the Peltier element 10 may be provided outside the smartwatch 40. For example, it is also conceivable that the Peltier element 10 is implemented in a ring.

In this manner, the present invention includes various embodiments etc., not described herein, as a matter of course. Thus, the technical scope of the present invention is only defined by invention specifying matters in the claims that are appropriate from the above description.

### INDUSTRIAL APPLICABILITY

The present embodiment can be widely applied in the field of information presentation and virtual reality in which a terminal such as a wearable device is used.

### REFERENCE SIGNS LIST

10 Peltier element
11 Heat conduction plate (heat radiation plate)
12 Heat conduction plate (heat absorption plate)
13 Thermoelectric module
20 Temperature stimulus control unit
30 Information reception unit

1. A temperature stimulus presentation device comprising:
a Peltier element, including one or more processors, configured to present a temperature stimulus; and
a temperature stimulus control unit, including one or more processors, configured to cause the Peltier element to generate a cold stimulus or a hot stimulus by receiving an input of type information which represents a type of information to be notified of and switching a direction of a current that flows through the Peltier element in correspondence with the type information.

2. The temperature stimulus presentation device according to claim 1, wherein
the temperature stimulus control unit is configured to switch the direction of the current to a direction that causes the Peltier element to generate a cold stimulus in a case where the type information indicates a notification with high urgency.

3. The temperature stimulus presentation device according to claim, further comprising
an information reception unit, including one or more processors, configured to receive the type information, wherein
the Peltier element is disposed so as to contact a human skin.

4. A temperature stimulus presentation method employed by a temperature stimulus presentation device, comprising:
a reception step of receiving type information which represents a type of information to be notified of; and
a temperature stimulus control step of causing a Peltier element to generate a cold stimulus or a hot stimulus by switching a direction of a current that flows through the Peltier element in accordance with whether or not the type information represents a notification with high urgency.

5. The temperature stimulus presentation method according to claim 4, further comprising:
switching the direction of the current to a direction to generate a cold stimulus in a case where the type information indicates a notification with high urgency.

6. The temperature stimulus presentation method according to claim 4, further comprising:
receiving the type information, wherein
the Peltier element is disposed so as to contact a human skin.
